(19) United States
(12) Patent Application Publication
(10) Pub. No.: US 2015/0279664 A1
(43) Pub. Date: Oct. 1, 2015

(54) METHOD FOR FABRICATING SEMICONDUCTOR DEVICES HAVING HIGH-PRECISION GAPS

(71) Applicant: Asia Pacific Microsystems, Inc., Hsinchu (TW)

(72) Inventor: Hung-Lin Yin, Hsinchu (TW)

(73) Assignee: ASIA PACIFIC MICROSYSTEMS, INC., Hsinchu (TW)

(21) Appl. No.: 14/670,875

(22) Filed: Mar. 27, 2015

(30) Foreign Application Priority Data
Apr. 1, 2014 (TW) 103112083

(51) Int. Cl. H01L 21/02; H01L 21/461; H01L 21/78; H01L 23/00

(52) U.S. Cl. CPC H01L 21/02255; H01L 24/03; H01L 24/06; H01L 21/461; H01L 21/02554; H01L 21/78

(57) ABSTRACT

The present disclosure provides a method for fabricating semiconductor devices having high-precision gaps. The method includes steps of providing a first wafer; forming two or more regions having various ion dosage concentrations on a first surface of the first wafer; thermally oxidizing the first wafer so as to grow oxide layers with various thicknesses on the first surface of the first wafer; and bonding a second wafer to the thickest oxide layer of the first wafer so as to form one or more gaps.

### PRIORITY TO A FOREIGN APPLICATION

The applicant claims priority to a foreign application, TW 103112083.

### FIELD OF THE INVENTION

This invention relates generally to a semiconductor manufacturing process. More particularly, the present invention relates to a method for fabricating semiconductor devices having high-precision gaps.

### BACKGROUND OF THE INVENTION

The sensitivity of capacitive sensors depends highly on the control quality of thickness of electrode membranes and dimensions of gaps between the electrodes. There are disadvantages in the manufacturing processes for the capacitive sensors currently available to the public. U.S. Pat. No. 5,013,396 to Wise et al. uses potassium hydroxide as an etchant to etch shallow recessed sections from the top of silicon wafers. The shallow recess sections later become gaps in capacitive transducers. It is more cost effective than using silicon on insulator (SOI) wafers. High control quality of thickness of electrode membranes is achieved. But, the gaps may not be uniform in dimensions. U.S. Pat. No. 5,445,991 to Lee performs an anodic reaction in an HF solution to make a diffusion region a porous silicon layer. The air-gap is formed by etching the porous silicon layer. It is more cost effective than using SOI wafers. High control quality of dimensions of gaps is achieved. But, an additional sealing process is required. The pairs of electrode membranes are not reliably insulated. Gaps of U.S. Pat. No. 5,706,565 to Sparks et al. are formed by etching wafers. Electrode membranes are formed by bonding of wafers. It is a relatively simple process. But, the dimensions of gaps are not well controlled. U.S. Pat. No. 6,958,255 to Khuri-Yakub et al. applies etching, multiple thermal oxidation, and bonding processes to fabricate ultrasonic transducers having high-precision gaps. But, the method is complicated and includes many process steps. It requires long fabrication time. U.S. Pat. No. 7,745,248 to Park et al. deposits and patterns an oxidation-blocking layer to form a post region and a cavity region on a substrate surface; and thermally oxidizes the substrate to grow one or more oxide posts from the post region. The post defines vertical critical dimensions of the device. High control quality of dimensions of gaps is achieved. But, the method is complicated and includes many process steps. It requires long fabrication time.

### SUMMARY OF THE INVENTION

The present disclosure provides a method for fabricating semiconductor devices having high-precision gaps. The method includes steps of providing a first wafer; forming two or more regions having various ion dosage concentrations on a first surface of the first wafer; thermally oxidizing the first wafer so as to grow oxide layers with various thicknesses on the first surface of the first wafer; and bonding a second wafer to the thickest oxide layer of the first wafer so as to form one or more gaps.

The present disclosure has numerous advantages over existing techniques of fabricating semiconductor devices having high-precision gaps. Oxide layers with various thicknesses grown from regions of wafers with various impurities by thermal oxidation. Vertical critical dimensions of gaps are defined by the oxide layers with various thicknesses. The method of the present disclosure is cost effective; takes short fabrication time; and ensures reliable insulation between electrodes. The method of the present disclosure may be applied to fabrication of capacitive sensors, ultrasound scanners, pressure sensors, and microfluidic devices.

### BRIEF DESCRIPTION OF THE DRAWINGS

FIG. 1 is a flowchart of a method for fabricating semiconductor devices having high-precision gaps in examples of the present disclosure.

FIG. 2A, FIG. 2B, FIG. 2C, and FIG. 2D are a series of cross-sectional views showing various processing steps for fabricating semiconductor devices having high-precision gaps in examples of the present disclosure.

FIG. 3A, FIG. 3B, and FIG. 3C are a series of cross-sectional views showing optional processing steps after various processing steps of FIG. 2A, FIG. 2B, FIG. 2C, and FIG. 2D in examples of the present disclosure.

FIG. 4A, FIG. 4B, and FIG. 4C are cross-sectional views of semiconductor devices fabricated by the method of FIG. 1 in examples of the present disclosure.

FIG. 5 are cross-sectional views of semiconductor devices prior to and after a bonding process in examples of the present disclosure.

FIG. 6A, FIG. 6B, FIG. 6C, and FIG. 6D are a series of cross-sectional views showing various processing steps for fabricating semiconductor devices having high-precision gaps in examples of the present disclosure.

FIG. 7A, FIG. 7B, and FIG. 7C are a series of cross-sectional views showing optional processing steps after various processing steps of FIG. 6A, FIG. 6B, FIG. 6C, and FIG. 6D in examples of the present disclosure.

FIG. 8 is a graph showing normalized thermal oxidation thickness versus dosage concentration of various ions in examples of the present disclosure.

### DETAILED DESCRIPTION OF THE INVENTION

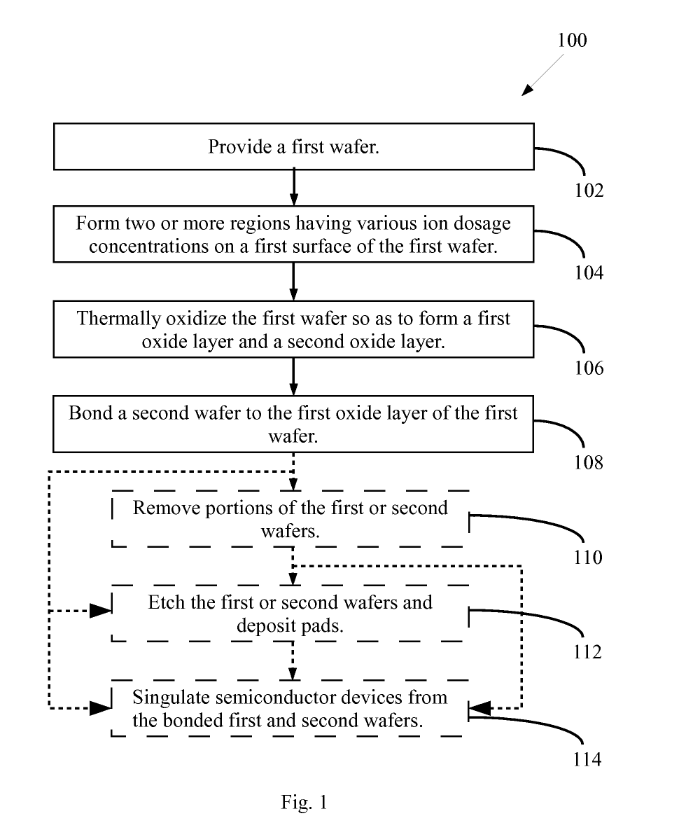

FIG. 1 is a flowchart of a method 100 for fabricating semiconductor devices having high-precision gaps in examples of the present disclosure. Method 100 may begin in block 102.

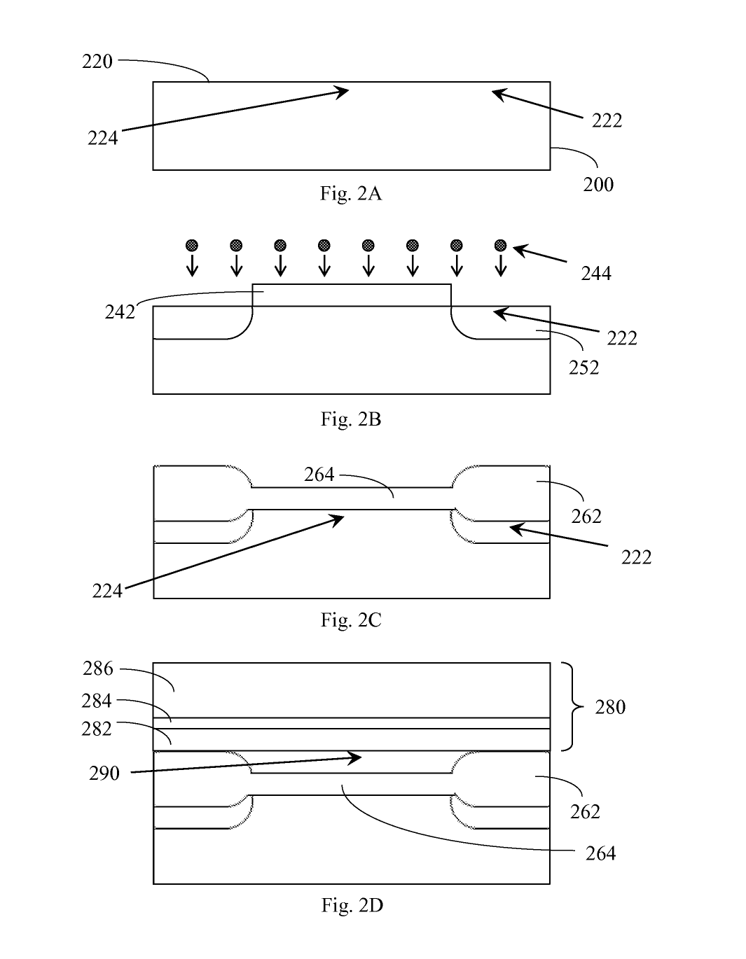

In block 102, a first wafer 200 (FIG. 2A) is provided. In one example, first wafer 200 is a single crystal silicon wafer. In another example, first wafer 200 is a polysilicon wafer. In still another example, first wafer 200 is a silicon carbide wafer. In still another example, first wafer 200 is a gallium arsenide wafer. In yet another example, first wafer 200 is a silicon-on-insulator wafer. The first wafer 200 may have an inherent ion dosage concentration. Block 102 may be followed by block 104.

In block 104, first wafer 200 has a first surface 220 (FIG. 2A). A first region 222 (FIG. 2A and FIG. 2B) characterized by a first oxidation rate and a second region 224 (FIG. 2A and FIG. 2B) characterized by a second oxidation rate are defined on first surface 220 of first wafer 200. First wafer 200 may contains multiple dies. First wafer 200 may contains multiple first regions 222 and multiple second regions 224. First region 222 may include many sub-regions. Second region 224 may include many sub-regions. Each sub-region of second region 224 is enclosed by at least one sub-region of first region 222. In examples of the present disclosure, a photoresist layer 242 (FIG. 2B) is formed on first surface 220 of first wafer 200. Photoresist layer 242 has openings so as to expose first region 222 of first surface 220 of first wafer 200. Implantation technology may be applied (FIG. 2B). In one example, first wafer 200 is an N type wafer that includes N type impurities. In another example, first wafer 200 is a P type wafer that includes P type impurities. A first set of impurities or ions 244 (FIG. 2B) are implanted through the openings of photoresist layer 242 into first region 222 of first surface 220 of first wafer 200. Volume 252 (FIG. 2B) under first region 222 is implanted with a higher dosage concentration of impurities or ions. Volume under second region 224 that is covered by photoresist layer 242 is not implanted with ions and has a lower dosage concentration of impurities or ions. Photoresist layer 242 is then removed from first surface 220 of first wafer 200. In examples of the present disclosure, ions 244 are selected from the group consisting of arsenic, phosphorus, antimony, and boron. In one example, first region 222 has a first type of ions with higher oxidation rate and second region 224 has a second type of ions having lower oxidation rate. In another example, first region 222 has a first type of ions with higher dosage concentration and second region 224 has the first type of ions having lower dosage concentration. Block 104 may be followed by block 106.

In block 106, first wafer 200 is thermally oxidized. A first oxide layer 262 (FIG. 2C) is formed on first region 222. A second oxide layer 264 (FIG. 2C) is formed on second region 224. In examples of the present disclosure, first region 222 is characterized by a higher oxidation rate. Second region 224 is characterized by a lower oxidation rate. First oxide layer 262 is thicker than second oxide layer 264. First region 222 may be located at the same height as second region 224 before thermal oxidation process. More materials in volume 252 are oxidized during thermal oxidation process. First region 222 may be located at a position lower than second region 224 after thermal oxidation process. Block 106 may be followed by block 108.

In block 108, a second wafer 280 (FIG. 2D) is bonded to first oxide layer 262 on first region 222 of first wafer 200. In one example, it applies fusion bonding to bond a silicon layer to an oxide layer. In another example, it applies plasma activated bonding to bond one oxide layer to another oxide layer. A gap 290 (FIG. 2D) is formed between second wafer 280 and second oxide layer 264. In examples of the present disclosure, second wafer 280 is selected from the group consisting of single crystal silicon wafer, polysilicon wafer, silicon carbide wafer, gallium arsenide wafer, and silicon-on-insulator wafer including a device layer 282 (FIG. 2D), a burned oxide layer (FIG. 2D), and a handle layer (FIG. 2D). Block 108 may be followed by optional block 110, optional block 112, or optional block 114.

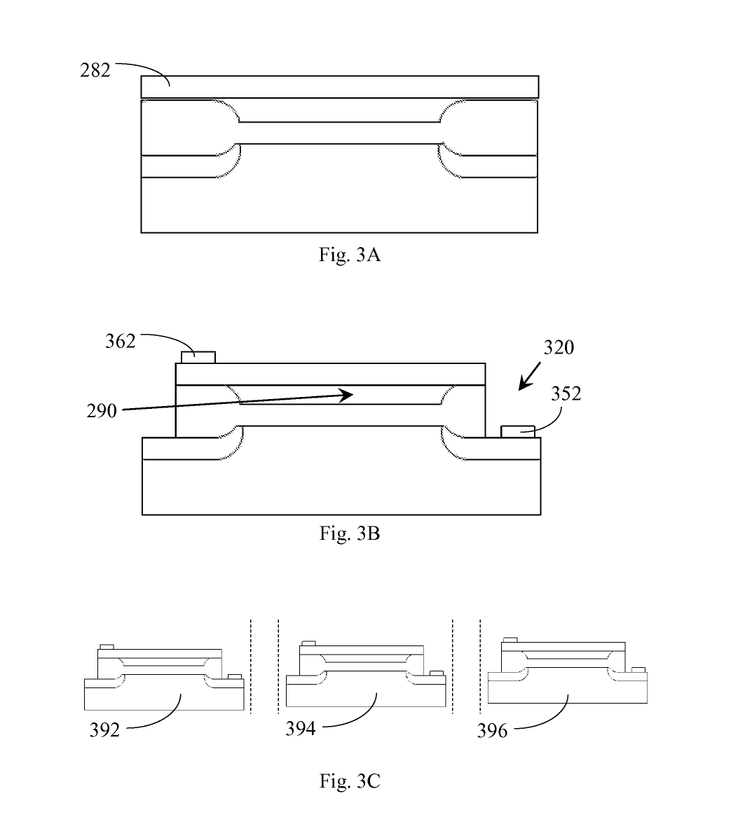

In optional block 110, portions of first wafer or portions of second wafer may be removed. The thickness of wafers may be reduced by a grinding or an etching process. In examples of the present disclosure, handle layer 286 (FIG. 2D) and burned oxide layer 284 (FIG. 2D) of a SOI wafer may be removed by a grinding process or an etching process. Device layer 282 (FIG. 3A) is still bonded to first wafer. Potassium hydroxide or hydrofluoric acid may be used in the etching process. Block 110 may be followed by optional block 112 or optional block 114.

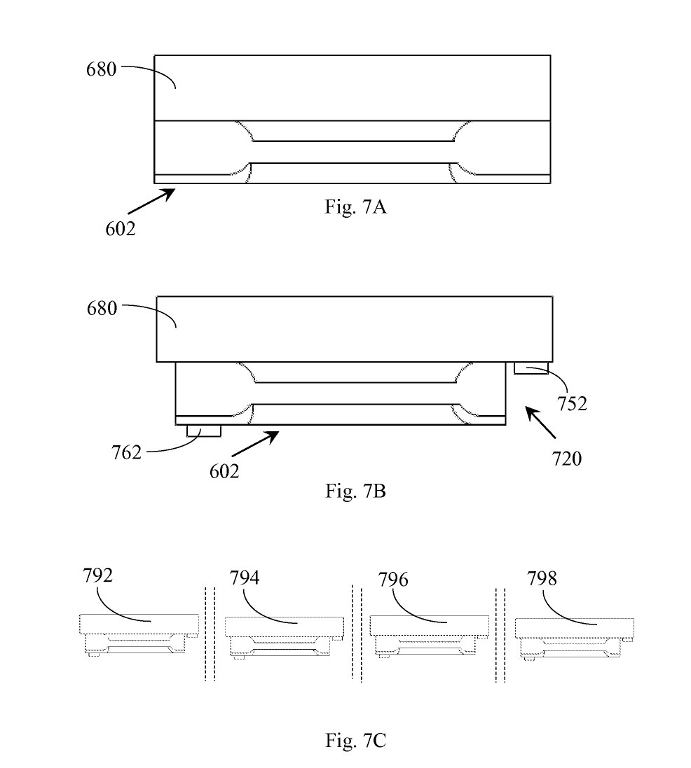

In optional block 112, second wafer 280 and oxide layer are etched to form cavity 320 (FIG. 3B) so as to expose portions of first surface 220 of first wafer 200. Pad 352 (FIG. 3B) is deposited on first surface of first wafer. Pad 362 (FIG. 3B) is deposited on device layer 282 of second wafer 280. Pad 352 is electrically connected to first wafer 200. Pad 362 is electrically connected to second wafer 280. In examples of the present disclosure, first wafer 200 is etched to form cavity 720 (FIG. 7B) so as to expose portions of second wafer 280. Pad 752 (FIG. 7B) is formed on second wafer. Pad 762 (FIG. 7B) is formed on first wafer 200. Pad 752 is electrically connected to second wafer 680. Pad 762 is electrically connected to device layer 602 of first wafer 200. Block 112 may be followed by optional block 114.

In optional block 114, semiconductor devices 392, 394, and 396 (FIG. 3C) are singulated from the bonded first and second wafers. Though three devices are shown in FIG. 3C, the bonded first and second wafers may contain various numbers of devices. In examples of the present disclosure, the singulated devices are capacitive sensors. A voltage potential may be applied to pad 352 (FIG. 3B) and another voltage potential may be applied to pad 362 (FIG. 3B). Capacitance value between two electrodes separated by gap 290 (FIG. 3B) changes when external pressure changes. Thus, external pressure value can be measured from the capacitance value.

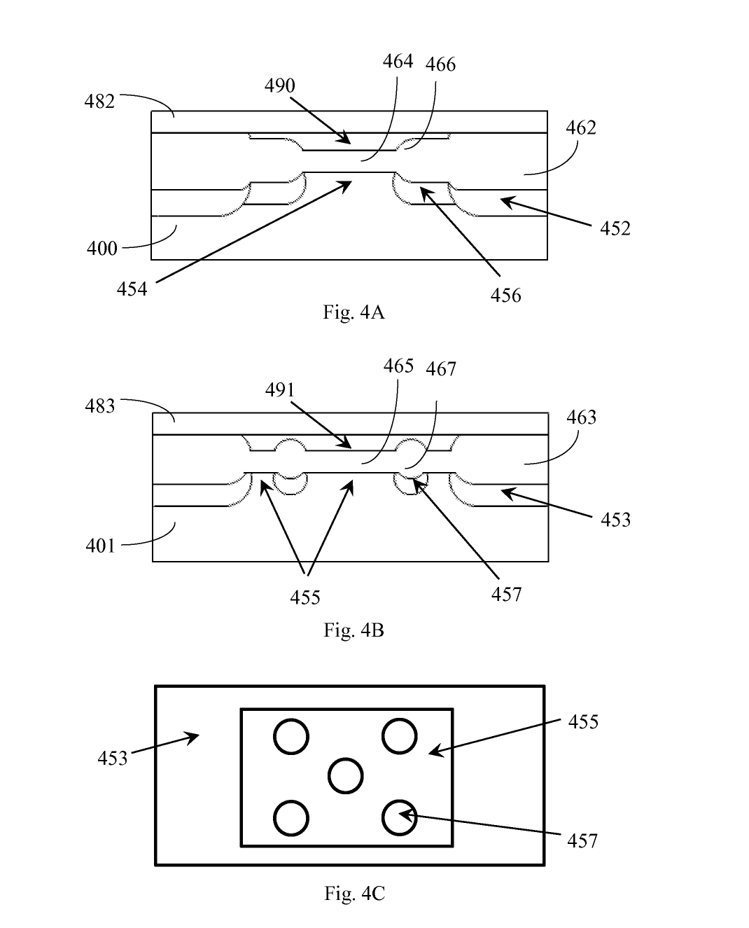

FIG. 4A is a cross-sectional view of a semiconductor device fabricated by the method of FIG. 1 in examples of the present disclosure. A first region 452 characterized by a first oxidation rate, a second region 454 characterized by a second oxidation rate and a third region 456 characterized by a third oxidation rate are defined on a first surface of a first wafer 400. First region 452 may include many sub-regions. Second region 454 may include many sub-regions. Third region 456 may include many sub-regions. Each sub-region of second region 454 is enclosed by at least one sub-region of third region 456. Each sub-region of third region 456 is enclosed by at least one sub-region of first region 452. The ion dosage concentration of first region 452 is higher than the ion dosage concentration of third region 456. The ion dosage concentration of third region 456 is higher than the ion dosage concentration of second region 454. The first oxidation rate is higher than the third oxidation rate. The third oxidation rate is higher than the second oxidation rate. First region 452, second region 454, and third region 456 may be located at the same height before thermal oxidation process. First region 452 may be located at a position lower than third region 456 after thermal oxidation process. Third region 456 may be located at a position lower than second region 454 after thermal oxidation process. After first wafer 400 is thermally oxidized, a first oxide layer 462 is formed on first region 452. A second oxide layer 464 is formed on second region 454. A third oxide layer 466 is formed on third region 456. First oxide layer 462 is thicker than third oxide layer 466. Third oxide layer 466 is thicker than second oxide layer 464. A second wafer 482 is bonded to first oxide layer 462 that is the thickest oxide layer. A gap 490 is formed between second wafer 482 and oxide layers 464 and 466. The distance between second wafer 482 and third oxide layer 466 is smaller than the distance between second wafer 482 and second oxide layer 464.

FIG. 4B is a cross-sectional view of a semiconductor device fabricated by the method of FIG. 1 in examples of the present disclosure. A first region 453 characterized by a first oxidation rate, a second region 455 characterized by a second oxidation rate and a third region 457 characterized by a third oxidation rate are defined on a first surface of a first wafer 401. Third region 457 is divided into sub-regions. Sub-regions of third region 457 are scattered within second region 455. The ion dosage concentration of first region 453 is higher than the ion dosage concentration of third region 457. The ion dosage concentration of third region 457 is higher than the ion dosage concentration of second region 455. In examples of the present disclosure, the impurities of ions of first region 453, second region 455, and third region 457 are selected from the group consisting of arsenic, phosphorus, antimony, and boron. The first oxidation rate is higher than the third oxidation rate. The third oxidation rate is higher than the second oxidation rate. First region 453, second region 455, and third region 457 may be located at the same height before thermal oxidation process. First region 453 may be located at a position lower than third region 457 after thermal oxidation process. Third region 457 may be located at a position lower than second region 455 after thermal oxidation process. After first wafer 401 is thermally oxidized, a first oxide layer 463 is formed on first region 453. A second oxide layer 465 is formed on second region 455. A third oxide layer 467 is formed on third region 457. First oxide layer 463 is thicker than third oxide layer 467. Third oxide layer 467 is thicker than second oxide layer 465. A second wafer 483 is bonded to first oxide layer 463 that is the thickest oxide layer. A gap 491 is formed between second wafer 483 and oxide layers 465 and 467. The distance between second wafer 483 and third oxide layer 467 is smaller than the distance between second wafer 483 and second oxide layer 465.

FIG. 4C is a cross-sectional view of a semiconductor device fabricated by the method of FIG. 1 in examples of the present disclosure. It is viewed along a direction perpendicular to a bottom surface of first wafer 401 of FIG. 4B. Second region 455 is enclosed by first region 453. Third region 457 is divided into sub-regions. Sub-regions of third region 457 are scattered within second region 455.

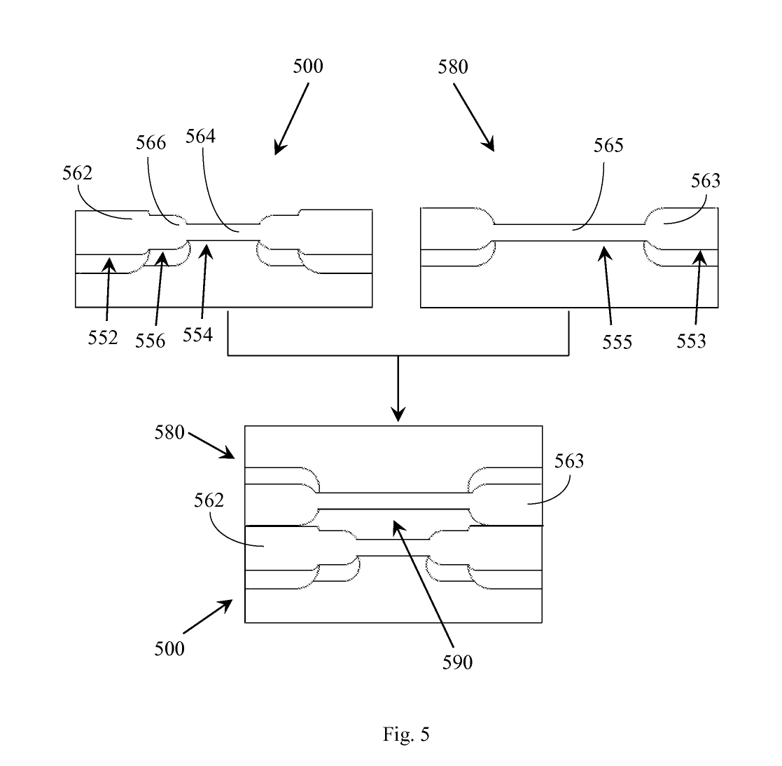

FIG. 5 are cross-sectional views of semiconductor devices prior to and after a bonding process in examples of the present disclosure. A first region 552 characterized by a first oxidation rate, a second region 554 characterized by a second oxidation rate and a third region 556 characterized by a third oxidation rate are defined on a first surface of a first wafer 500. The ion dosage concentration of first region 552 is higher than the ion dosage concentration of third region 556. The ion dosage concentration of third region 556 is higher than the ion dosage concentration of second region 554. The first oxidation rate is higher than the third oxidation rate. The third oxidation rate is higher than the second oxidation rate. After first wafer 500 is thermally oxidized, a first oxide layer 562 is formed on first region 552. A second oxide layer 564 is formed on second region 554. A third oxide layer 566 is formed on third region 556. First oxide layer 562 is thicker than third oxide layer 566. Third oxide layer 566 is thicker than second oxide layer 564. A fourth region 553 characterized by a fourth oxidation rate and a fifth region 555 characterized by a fifth oxidation rate are defined on a first surface of a second wafer 580. The ion dosage concentration of fourth region 553 is higher than the ion dosage concentration of fifth region 555. The fourth oxidation rate is higher than the fifth oxidation rate. After second wafer 580 is thermally oxidized, a fourth oxide layer 563 is formed on fourth region 553. A fifth oxide layer 565 is formed on fifth region 555. Fourth oxide layer 563 is thicker than fifth oxide layer 565. Fourth oxide layer 563 of second wafer 580 is bonded to first oxide layer 562 of first wafer 500. A gap 590 is formed between fifth oxide layer 565 of second wafer 580 and oxide layers 564 and 566 of first wafer 500. The distance between fifth oxide layer 565 and third oxide layer 566 is smaller than the distance between fifth oxide layer 565 and second oxide layer 564. The height of gap 590 is increased by bonding first wafer 500 and second wafer 580 with increased thicknesses of oxide layers.

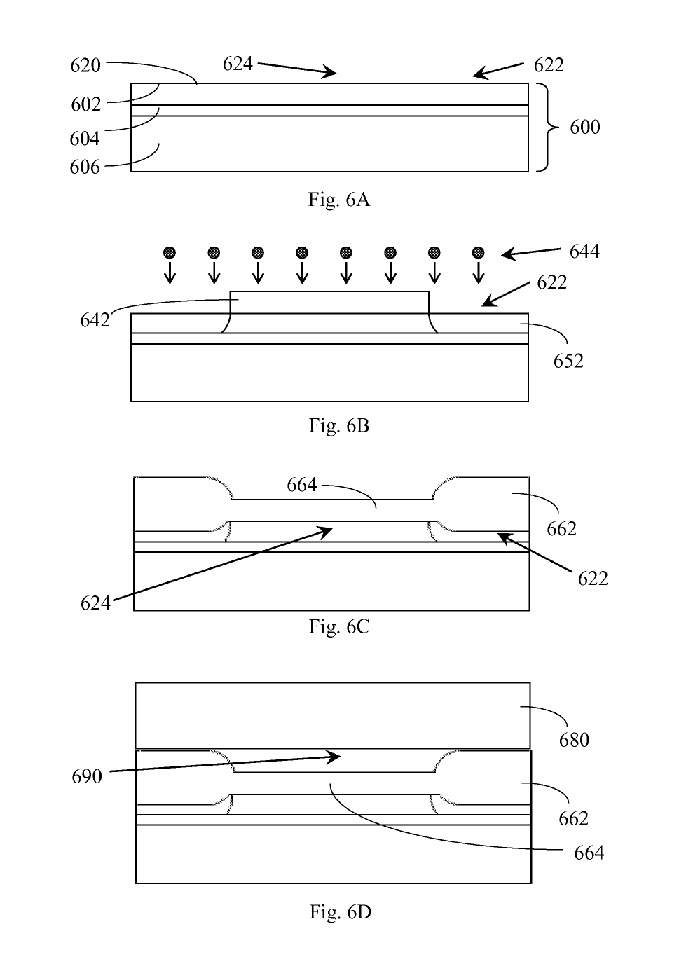

FIG. 6A, FIG. 6B, FIG. 6C, and FIG. 6D are a series of cross-sectional views showing various processing steps for fabricating semiconductor devices having high-precision gaps in examples of the present disclosure. In FIG. 6A, a first wafer 600 is provided. First wafer 600 is a silicon-on-insulator wafer including a device layer 602, a burned oxide layer 604, and a handle layer 606. Device layer 602 has a first surface 620. A first region 622 characterized by a first oxidation rate and a second region 624 characterized by a second oxidation rate are defined on first surface 620. First wafer 600 may contains multiple dies. First wafer 600 may contains multiple first regions 622 and multiple second regions 624.

In FIG. 6B, a photoresist layer 642 is formed on first surface 620. Photoresist layer 642 has openings so as to expose first region 622. A first set of impurities or ions 644 are implanted through the openings of photoresist layer 642 into first region 622. Volume 652 under first region 622 is implanted with a higher dosage concentration of impurities or ions. Volume under second region 624 that is covered by photoresist layer 642 is not implanted with ions and has a lower dosage concentration of impurities or ions. Photoresist layer 642 is then removed from first surface 620.

In FIG. 6C, first wafer 600 is thermally oxidized. A first oxide layer 662 is formed on first region 622. A second oxide layer 664 is formed on second region 624. In examples of the present disclosure, first region 622 is characterized by a higher oxidation rate. Second region 624 is characterized by a lower oxidation rate. First oxide layer 662 is thicker than second oxide layer 664.

In FIG. 6D, a second wafer 680 is bonded to first oxide layer 662 on first region 622 of first wafer 600. A gap 690 is formed between second wafer 680 and second oxide layer 664.

FIG. 7A, FIG. 7B, and FIG. 7C are a series of cross-sectional views showing optional processing steps after various processing steps of FIG. 6A, FIG. 6B, FIG. 6C, and FIG. 6D in examples of the present disclosure. In FIG. 7A, burned oxide layer 604 (FIG. 6A) and handle layer 606 (FIG. 6A) are removed from first wafer 600. Second wafer 680 is still bonded to first oxide layer 662 of first wafer 600.

In FIG. 7B, device layer 602 and oxide layer are etched to form cavity 720 so as to expose portions of a surface of second wafer 680. Pad 752 is deposited on second wafer 680. Pad 762 is deposited on device layer 602. Pad 752 is electrically connected to second wafer 680. Pad 762 is electrically connected to device layer 602.

In FIG. 7C, semiconductor devices 792, 794, 796, and 798 are singulated from the bonded first and second wafers. Though four devices are shown in FIG. 7C, the bonded first and second wafers may contain various numbers of devices.

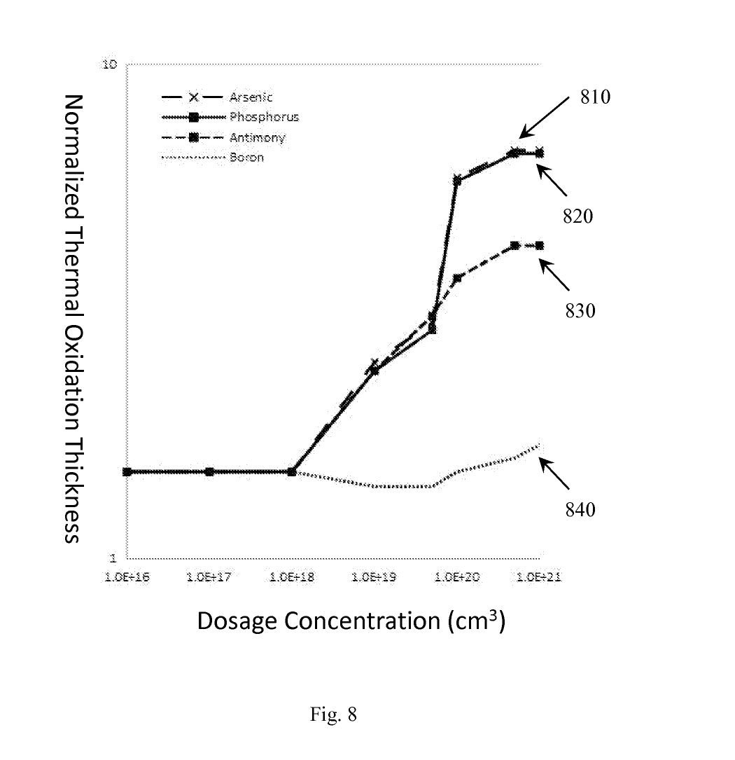

FIG. 8 is a graph showing normalized thermal oxidation thickness versus dosage concentration of various ions in examples of the present disclosure. Curve 810 is for Arsenic ions. Curve 820 is for Phosphorous ions. Curve 830 is for Antimony ions. Curve 840 is for Boron ions. Arsenic ions, Phosphorous ions, and Antimony ions are N type impurities. Boron ions are P type impurities. In examples of the present disclosure, Arsenic ions with 1.0E21 dosage concentration may be implanted into a first region characterized by a higher oxidation rate and Antimony ions with 1.0E21 dosage concentration may be implanted into a second region characterized by a lower oxidation rate.

Those of ordinary skill in the art may recognize that modifications of the embodiments disclosed herein are possible. For example, the number of dies in a bonded wafer may vary. Other modifications may occur to those of ordinary kill in this art, and all such modifications are deemed to fall within the purview of the present invention, as defined by the claims.

1. A method for fabricating semiconductor devices, the method comprising the steps of:
providing a first wafer;
forming two or more regions on a first surface of the first wafer, the two or more regions including a first region characterized by a first oxidation rate and a second region characterized by a second oxidation rate, wherein the first region has a first ion dosage concentration, the second region has a second ion dosage concentration, and the first oxidation rate is higher than the second oxidation rate;
thermally oxidizing the first wafer so as to form a first oxide layer on the first region and a second oxide layer on the second region, wherein the first oxide layer is thicker than the second oxide layer; and
bonding a second wafer to the first oxide layer of the first wafer so as to form one or more gaps between the second wafer and the second oxide layer of the first wafer.

2. The method of claim 1, wherein the first ion dosage concentration is higher than the second ion dosage concentration.

3. The method of claim 1, wherein the first region contains a first type of ions and the second region contains a second type of ions.

4. The method of claim 3, wherein the first and second types of ions are selected from the group consisting of arsenic, phosphorus, antimony, and boron.

5. The method of claim 1, wherein the first and second wafers are selected from the group consisting of single crystal silicon wafer, polysilicon wafer, silicon carbide wafer, gallium arsenide wafer, and silicon-on-insulator wafer.

6. The method of claim 1, wherein
the first region includes a plurality of first sub-regions; and
the second region includes a plurality of second sub-regions; and wherein
the plurality of second sub-regions each are enclosed by a sub-region of the plurality of first sub-regions.

7. The method of claim 1, further comprising:
after bonding the second wafer to the first oxide layer of the first wafer, removing portions of the first or second wafers.

8. The method of claim 1, further comprising:
after bonding the second wafer to the first oxide layer of the first wafer,
etching the second wafer and the first oxide layer so as to expose portions of the first surface of the first wafer; and
forming one or more metal pads on the exposed portions of the first surface of the first wafer and one or more metal pads on a surface of the second wafer.

9. The method of claim 1, further comprising:
after bonding the second wafer to the first oxide layer of the first wafer,
etching the first wafer and the first oxide layer so as to expose portions of a surface of the second wafer; and
forming one or more metal pads on the exposed portions of the surface of the second wafer and one or more metal pads on the first surface of the first wafer.

10. The method of claim 1, further comprising:
after bonding the second wafer to the first oxide layer of the first wafer, singulating semiconductor devices from the bonded first and second wafers.

11. The method of claim 1, further comprising:
after bonding the second wafer to the first oxide layer of the first wafer, removing portions of the first or second wafers;
etching the second wafer and the first oxide layer so as to expose portions of the first surface of the first wafer;
forming one or more metal pads on the exposed portions of the first surface of the first wafer and one or more metal pads on a surface of the second wafer; and
singulating semiconductor devices from the bonded first and second wafers.

12. The method of claim 1, further comprising:
after bonding the second wafer to the first oxide layer of the first wafer, removing portions of the first or second wafers;
etching the first wafer and the first oxide layer so as to expose portions of a surface of the second wafer;
forming one or more metal pads on the exposed portions of the surface of the second wafer and one or more metal pads on the first surface of the first wafer; and
singulating semiconductor devices from the bonded first and second wafers.

13. The method of claim 1, wherein
the two or more regions further include a third region characterized by a third oxidation rate;
the third oxidation rate is lower than the first oxidation rate and is higher than the second oxidation rate;
a third oxide layer is formed on the third region in the step of thermally oxidizing the first wafer; and
the third oxide layer is thinner than the first oxide layer and is thicker than the second oxide layer.

14. The method of claim 13, wherein
the first region includes a plurality of first sub-regions;
the second region includes a plurality of second sub-regions; and
the third region includes a plurality of third sub-regions; and wherein
the plurality of second sub-regions each are enclosed by a sub-region of the plurality of third sub-regions; and
the plurality of third sub-regions each are enclosed by a sub-region of the plurality of first sub-regions.

15. The method of claim 1, further comprising:
after thermally oxidizing the first wafer and prior to bonding the second wafer to the first oxide layer of the first wafer, thermally oxidizing the second wafer so as to form an oxide layer on a surface of the second wafer, wherein bonding the second wafer to the first oxide layer of the first wafer is to bond the oxide layer on the surface of the second wafer to the first oxide layer of the first wafer.

16. The method of claim 1, further comprising:
after thermally oxidizing the first wafer and prior to bonding the second wafer to the first oxide layer of the first wafer,
forming two or more regions on a first surface of the second wafer, the two or more regions on the first surface of the second wafer including a third region characterized by a third oxidation rate and a fourth region characterized by a fourth oxidation rate, wherein the third oxidation rate is higher than the fourth oxidation rate; and
thermally oxidizing the second wafer so as to form a third oxide layer on the third region and a fourth oxide layer on the fourth region, wherein the third oxide layer is thicker than the fourth oxide layer, wherein bonding the second wafer to the first oxide layer of the first wafer is to bond the third oxide layer of the second wafer to the first oxide layer of the first wafer.
